(19) United States
(12) Patent Application Publication
(10) Pub. No.: US 2024/0381651 A1
(43) Pub. Date: Nov. 14, 2024

(54) Semiconductor Memory Structures And Method Of Forming The Same

(71) Applicant: Taiwan Semiconductor Manufacturing Company, Ltd., Hsinchu (TW)

(72) Inventors: Hung-Chang Sun, Kaohsiung City (TW); Sheng-Chih Lai, Hsinchu County (TW); Cheng-Jun Wu, Hsinchu (TW); Yu-Wei Jiang, Hsinchu (TW); Feng-Cheng Yang, Hsinchu County (TW); Chung-Te Lin, Tainan City (TW)

(21) Appl. No.: 18/781,431

(22) Filed: Jul. 23, 2024

Related U.S. Application Data
(62) Division of application No. 17/464,460, filed on Sep. 1, 2021.
(60) Provisional application No. 63/154,121, filed on Feb. 26, 2021.

(51) Int. Cl. H10B 51/00; H01L 21/28; H01L 29/08

(52) U.S. Cl. CPC H10B 51/00; H01L 29/0843; H01L 29/40111

(57) ABSTRACT

A semiconductor memory structure includes a ferroelectric layer and a channel layer formed over the ferroelectric layer. The structure also includes a source structure and a drain structure formed over the channel layer. The structure further includes a first isolation structure formed between the source structure and the drain structure. The source structure extends over the cap layer and towards the drain structure.

### CROSS REFERENCE TO RELATED APPLICATIONS

This application is divisional of U.S. application Ser. No. 17/464,460 filed Sep. 1, 2021, which claims the benefit of U.S. Provisional Application No. 63/154,121, filed on Feb. 26, 2021, the entirety of which are incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating or interlayer dielectric (ILD) structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at increasingly smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1, 1B-1, 1C-1, 1D-1, 1E-1, 1F-1, 1G-1, 1H-1, 1I-1, 1J-1, 1K-1, 1L-1, 1M-1 are perspective representations of various stages of forming a semiconductor memory structure, in accordance with some embodiments of the disclosure.

FIGS. 1A-2, 1B-2, 1C-2, 1D-2, 1E-2, 1F-2, 1G-2, 1H-2, 1I-2, 1J-2, 1K-2, 1L-2, 1M-2 are top views of various stages of forming the semiconductor memory structure as depicted in FIGS. 1A-1, 1B-1, 1C-1, 1D-1, 1E-1, 1F-1, 1G-1, 1H-1, 1I-1, 1J-1, 1K-1, 1L-1, 1M-1, respectively, in accordance with some embodiments of the disclosure.

FIGS. 1G-3 and 1J-3 are cross-sectional views of the semiconductor memory structure along line 3-3 as depicted in FIGS. 1G-1 and 1J-2, respectively, in accordance with some embodiments of the disclosure.

FIG. 1M-3 is a cross-sectional view of the semiconductor memory structure along line 3-3 as depicted in FIG. 1M-1, in accordance with some embodiments of the disclosure.

FIG. 2 is a top view of a semiconductor memory structure, in accordance with some embodiments of the disclosure.

FIG. 3 is a perspective representation of the semiconductor memory structure as depicted in FIG. 2, in accordance with some embodiments of the disclosure.

FIG. 4 is a top view of a semiconductor memory structure, in accordance with some embodiments of the disclosure.

FIGS. 5A, 5B, 5C, 5D, 5E, 5F, 5G, and 5H are top views of various stages of forming a semiconductor memory structure, in accordance with some embodiments of the disclosure.

FIGS. 6A-1, 6B, 6C-1, 6D, and 6E are top views of various stages of forming a semiconductor memory structure, in accordance with some embodiments of the disclosure.

FIGS. 6A-2 and 6C-2 are cross-sectional views of a various stages of forming a semiconductor memory structure, in accordance with some embodiments of the disclosure.

FIGS. 7A, 7B, 7C, 7D, 7E, and 7F are cross-sectional views of various stages of forming a semiconductor memory structure, in accordance with some embodiments of the disclosure.

FIGS. 8A, 8B, 8C, and 8D are cross-sectional views of various stages of forming a semiconductor memory structure, in accordance with some embodiments of the disclosure.

FIGS. 9A, 9B, 9C, 9D, 9E, and 9F are cross-sectional views of various stages of forming a semiconductor memory structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Herein, the terms “around,” “about,” “substantial” usually mean within 20% of a given value or range, and better within 10%, 5%, or 3%, or 2%, or 1%, or 0.5%. It should be noted that the quantity herein is a substantial quantity, which means that the meaning of “around,” “about,” “substantial” are still implied even without specific mention of the terms “around,” “about,” “substantial.”

Embodiments for forming a semiconductor memory structure are provided. A method of forming the semiconductor memory structure may include forming a source structure extending more than the drain structure extends. The memory window of the semiconductor memory structure may be improved. The cell density may be increased, and the on-current of the semiconductor memory structure may be higher.

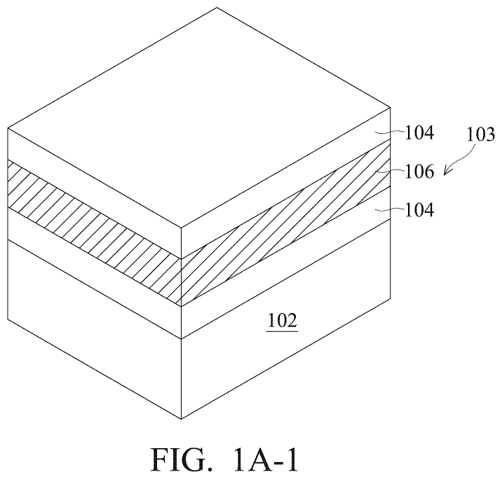

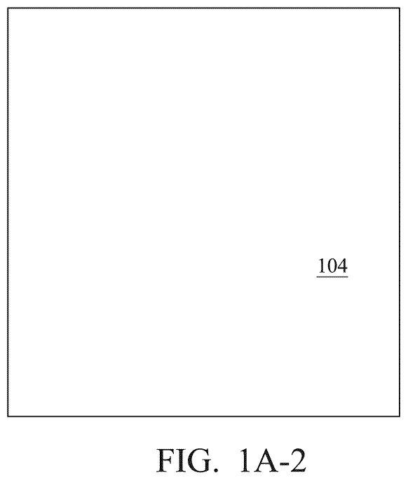

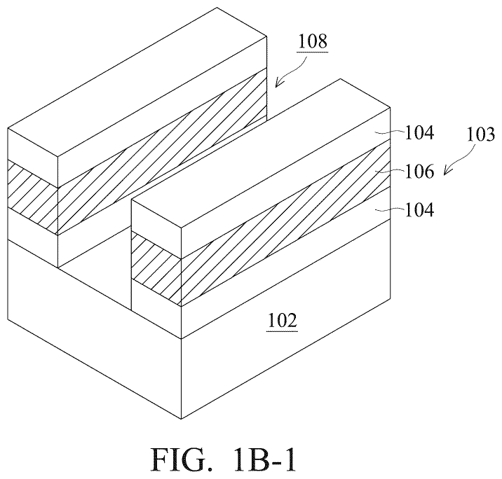

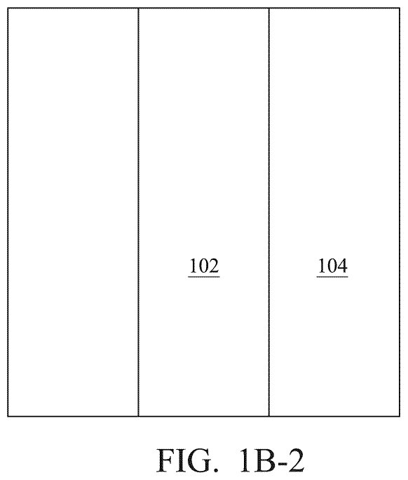

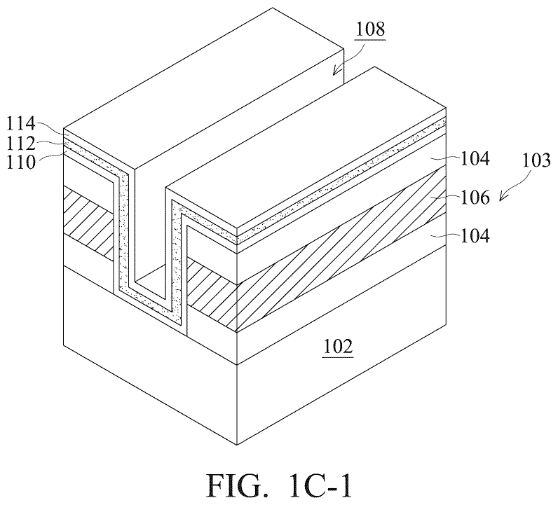

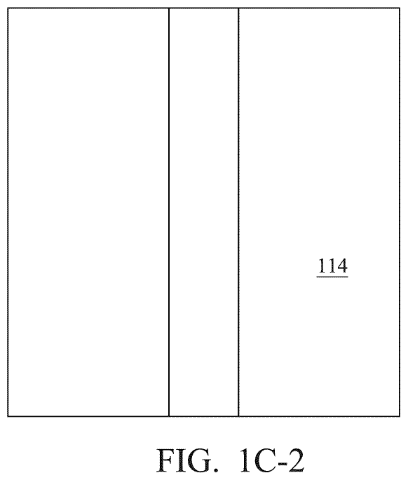

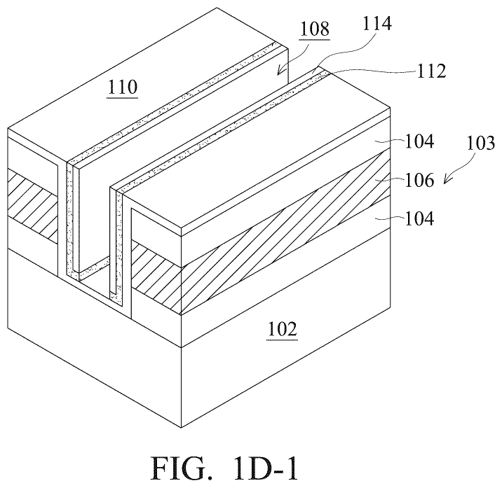

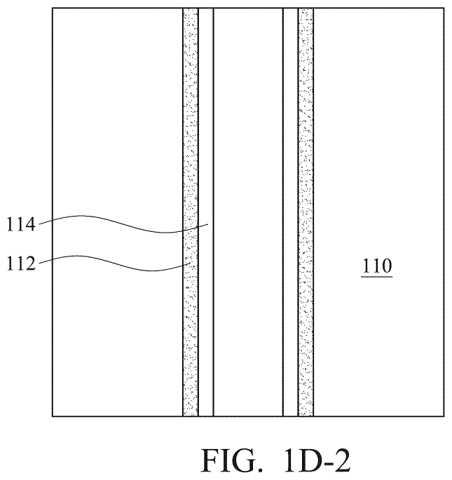

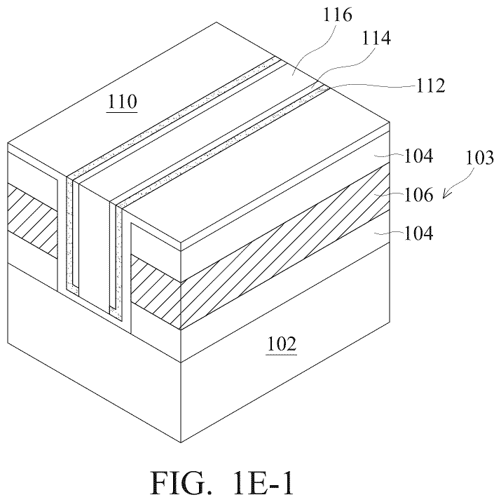

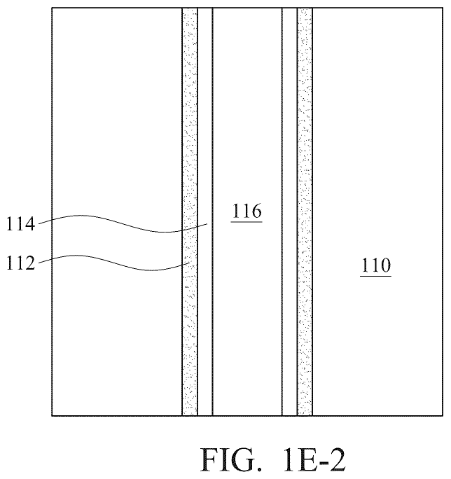

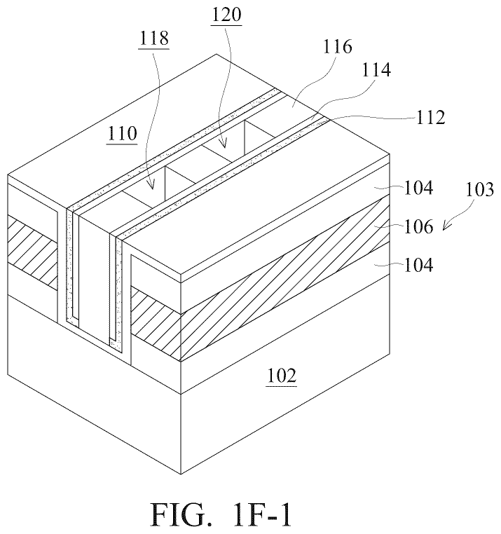

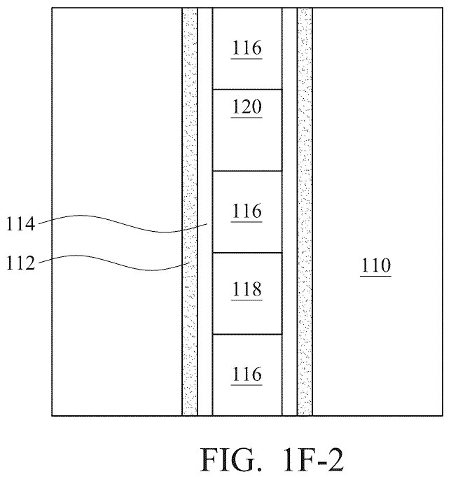

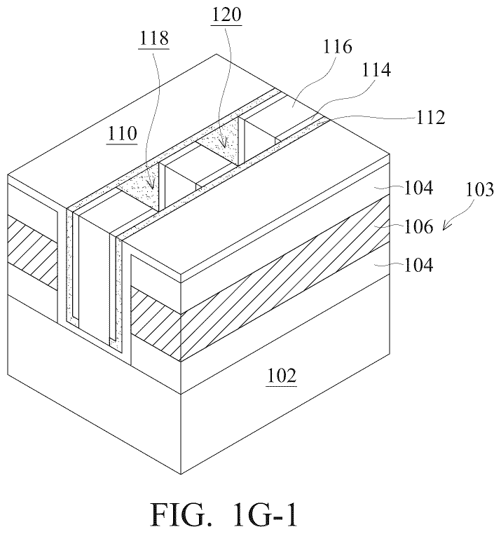

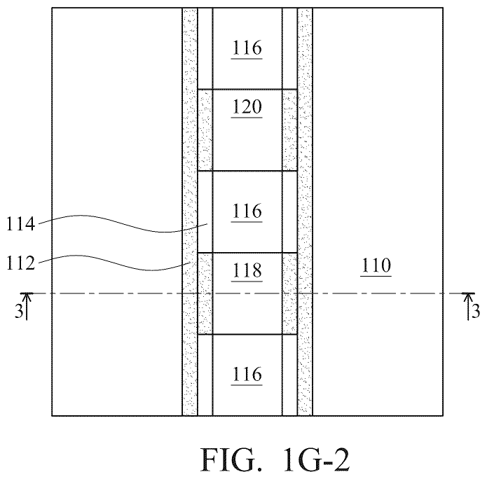

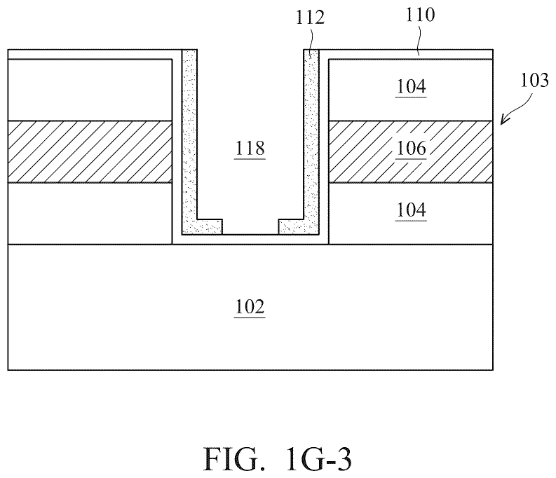

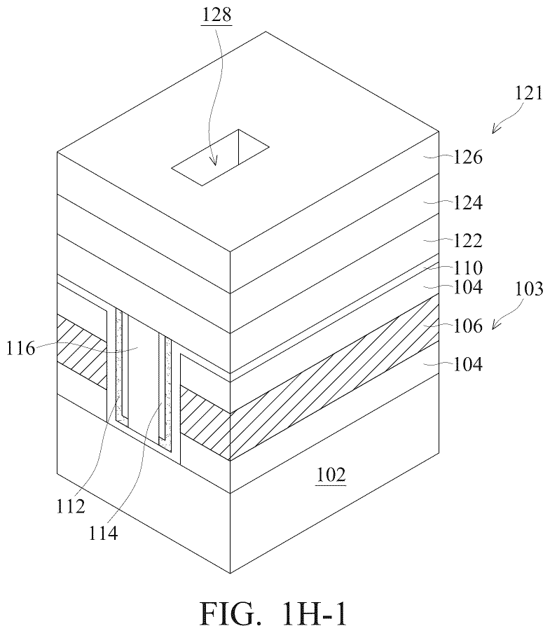

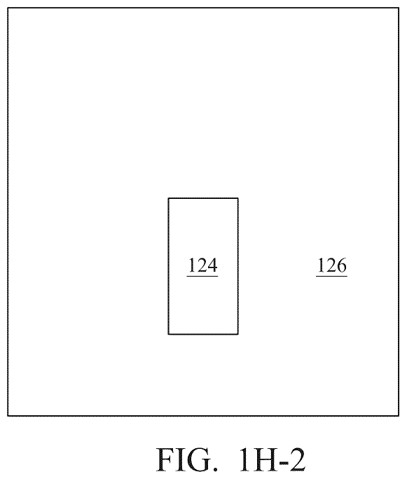

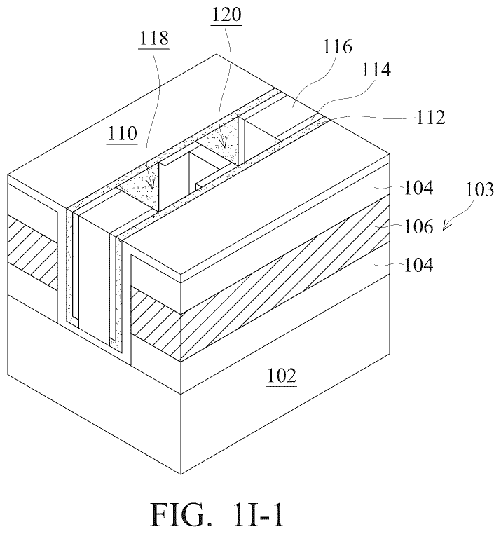

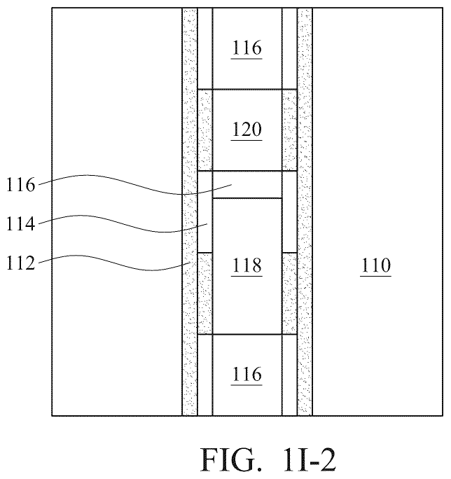

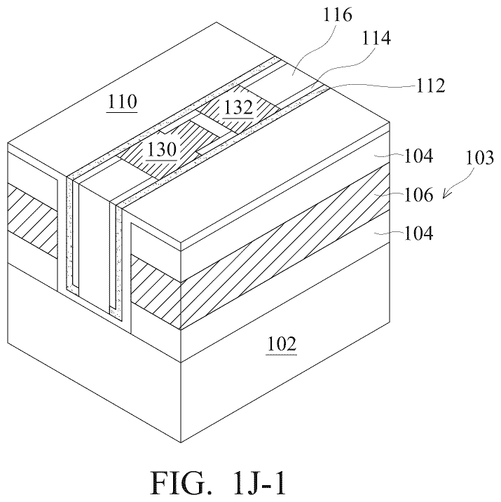

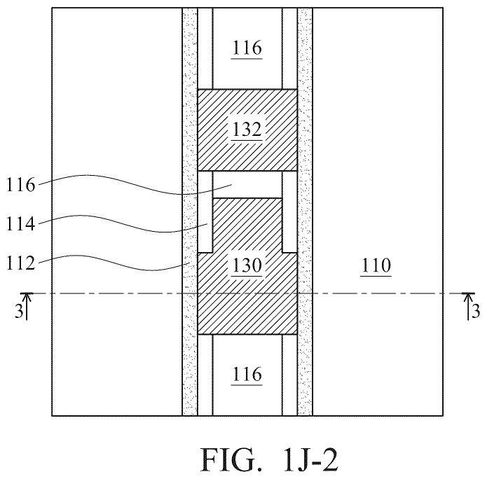

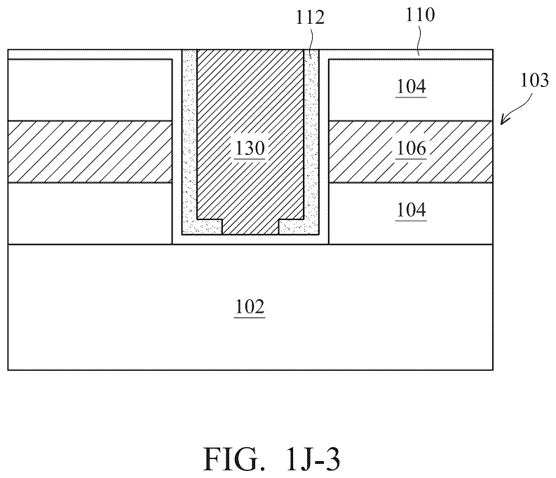

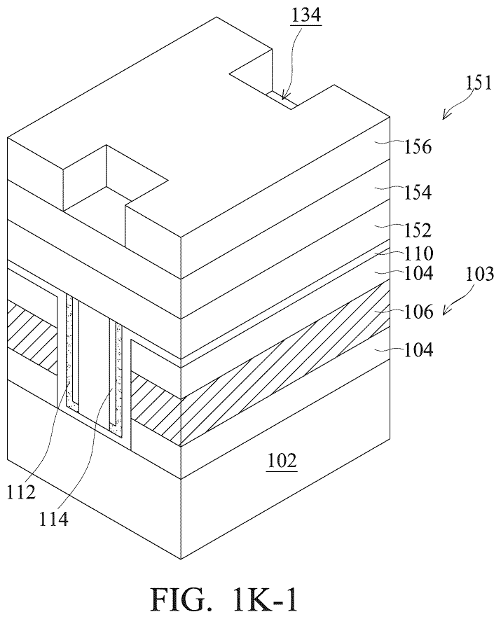

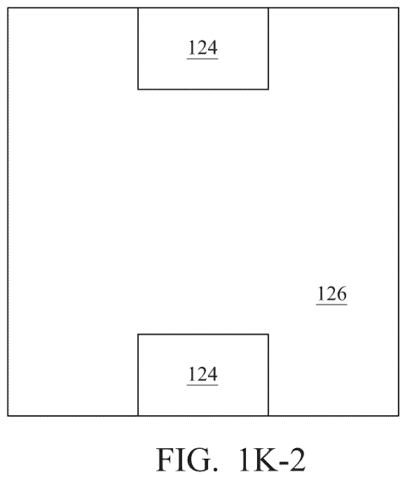

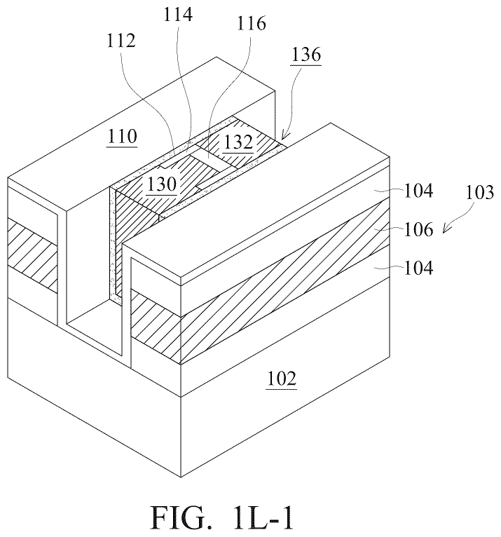

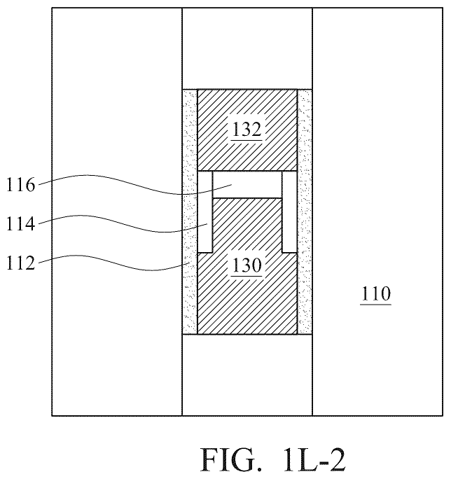

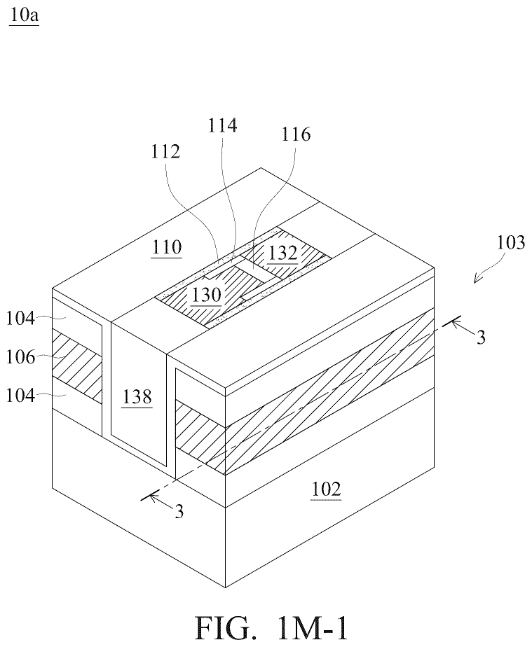

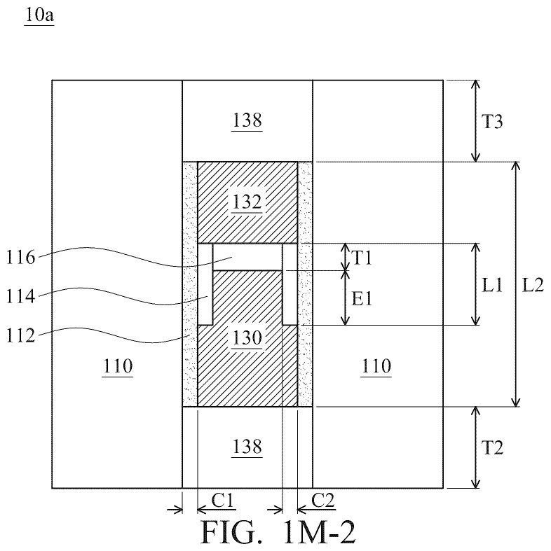

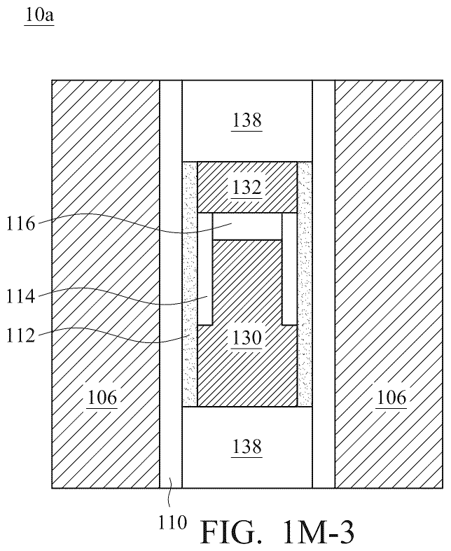

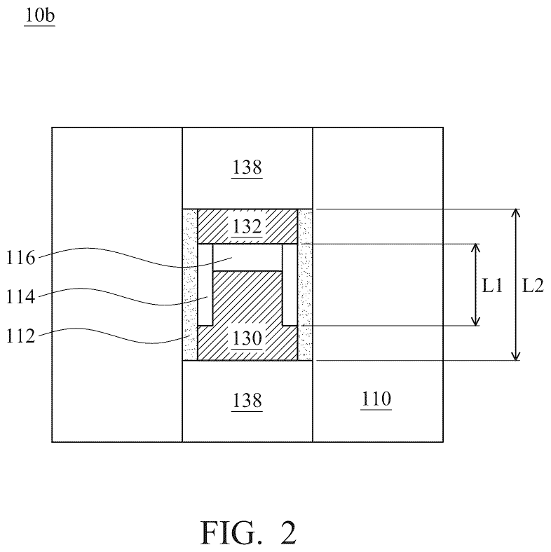

FIGS. 1A-1, 1B-1, 1C-1, 1D-1, 1E-1, IF-1, 1G-1, 1H-1, 1I-1, 1J-1, 1K-1, 1L-1, 1M-1 are perspective representations of various stages of forming a semiconductor memory structure 10a, in accordance with some embodiments of the disclosure. FIGS. 1A-2, 1B-2, 1C-2, 1D-2, 1E-2, 1F-2, 1G-2, 1H-2, 1I-2, 1J-2, 1K-2, 1L-2, 1M-2 are top views of various stages of forming the semiconductor memory structure 10a, in accordance with some embodiments of the disclosure.

A substrate 102 is provided as shown in FIG. 1A-1 in accordance with some embodiments. The substrate 102 may be a semiconductor wafer such as a silicon wafer. The substrate 102 may also include other elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium nitride, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. The substrate 102 may include an epitaxial layer. For example, the substrate 102 may include an epitaxial layer overlying a bulk semiconductor. In addition, the substrate 102 may also include a semiconductor on insulator (SOI). The SOI substrate may be fabricated by a wafer bonding process, a silicon film transfer process, a separation by implantation of oxygen (SIMOX) process, other applicable methods, or combinations thereof. The substrate 102 may be an N-type substrate. The substrate 102 may be a P-type substrate.

Next, a stack 103 including isolation layers 104 and a gate layer 106 are formed over the substrate 102, as shown in FIGS. 1A-1 and 1A-2 in accordance with some embodiments. As shown in FIG. 1A-1, the gate layer 106 is sandwiched between the isolation layers 104. The isolation layers 104 may include silicon oxide, silicon nitride, silicon oxynitride, fluoride-doped silicate glass (FSG), other low-k (having a dielectric constant less than that of silicon oxide, which is about 3.9) dielectric materials, or combinations thereof. The isolation layers 104 may be deposited by a deposition process, such as a chemical vapor deposition (CVD) process, a spin-on-glass process, other applicable processes, or combinations thereof.

The gate layer 106 may include polycrystalline-silicon (poly-Si), poly-crystalline silicon-germanium (poly-SiGe), metals (e.g., tungsten, titanium, aluminum, copper, molybdenum, nickel, platinum, the like, or combinations thereof), metal alloys, metal-nitrides (e.g., tungsten nitride, molybdenum nitride, titanium nitride, and tantalum nitride, the like, or combinations thereof), metal-silicides (e.g., tungsten silicide, titanium silicide, cobalt silicide, nickel silicide, platinum silicide, erbium silicide, the like, or combinations thereof), metal-oxides (e.g., ruthenium oxide, indium tin oxide, the like, or combinations thereof), other applicable materials, or combinations thereof. The gate layer 106 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or combinations thereof.

Afterwards, a photoresist layer may be formed over the isolation layer 104 (not shown). The photoresist layer may be patterned by a patterning process. The patterning process may include a photolithography process and an etching process. Examples of photolithography processes include photoresist coating (e.g., spin-on coating), soft baking, mask aligning, exposure, post-exposure baking, developing the photoresist, rinsing, and drying (e.g., hard baking). The etching process may be a dry etching process or a wet etching process. As a result, a patterned stack 103 is obtained and an opening 108 is formed in the stack 103 exposing the substrate 102, as shown in FIGS. 1B-1 and 1B-2 in accordance with some embodiments. Afterwards, the patterned photoresist layer is removed.

Next, a ferroelectric layer 110, a channel layer 112, and a cap layer (or capping layer) 114 are sequentially deposited over the stack 103 and in the opening 108, as shown in FIGS. 1C-1 and 1C-2 in accordance with some embodiments. In some embodiments, the ferroelectric layer 110, a channel layer 112, and a cap layer 114 are conformally deposited over the stack 103 and in the opening 108. In some embodiments as shown in FIG. 1C-1, the gate layer 106 is in direct contact with the ferroelectric layer 110.

In the present embodiments, the ferroelectric layer 110 includes a ferroelectric material that exhibits electrically switchable polarization. In some embodiments, the ferroelectric layer 110 includes HfOₓ, AlOₓ, ZrOₓ, HfZrOₓ, other applicable ferroelectric materials, or combinations thereof. The ferroelectric layer 110 may be formed by a CVD process, a physical vapor deposition process (PVD), an atomic layer deposition process (ALD), other suitable processes, or combinations thereof.

The channel layer 112 may include metal oxide such as indium gallium zinc oxide (IGZO), indium gallium zinc tin oxide (IGZTO), SiGe, germanium, other applicable materials, or combinations thereof. The channel layer 112 may be formed by a CVD process, a PVD process, an ALD process, other suitable processes, or combinations thereof.

The cap layer 114 may include aluminum oxide (AlOₓ), silicon oxide (SiOₓ), hafnium oxide (HfOₓ), silicon, other applicable materials, or combinations thereof. The cap layer 114 may be configured to protect the channel layer 112 during subsequent etching process. The cap layer 114 may be formed by a CVD process, a PVD process, an ALD process, other suitable processes, or combinations thereof.

Next, an etching process is performed to remove portions of the cap layer 114 and the channel layer 112 over a bottom surface of the opening 108 and top surface of the stack 103, as shown in FIGS. 1D-1 and 1D-2 in accordance with some embodiments. As shown in FIGS. 1D-1 and 1D-2, top surfaces of the ferroelectric layer 110 over the stack 103 and in the opening 108 are exposed after the etching process. The etching process may be a dry etching process or a wet etching process. In some embodiments, the cap layer 114 and the channel layer 112 are etched by a dry etching process. The dry etching process may include using a fluorine-based etchant gas, such as SF₆, CₓF_{y} (where x and y are positive integers), NF₃, or combinations thereof.

Next, an isolation structure 116 is formed in the opening 108 as shown in FIGS. 1E-1 and 1E-2 in accordance with some embodiments. The isolation structure 116 may include silicon oxide, silicon nitride, silicon oxynitride, fluoride-doped silicate glass (FSG), other low-k dielectric materials, or combinations thereof. The isolation structure 116 may be deposited by a deposition process, such as a CVD process, a spin-on-glass process, other applicable processes, or combinations thereof.

Afterwards, the isolation structure 116 may be planarized to expose the top surface of the ferroelectric layer 110, the channel layer 112, and the cap layer 114, as shown in FIGS. 1E-1 and 1E-2 in accordance with some embodiments. The isolation structure 116 may be planarized by a chemical mechanical polishing (CMP) process.

Afterwards, a photoresist layer may be formed over the isolation structure 116 (not shown). The photoresist layer may be patterned by a patterning process. The patterning process may include a photolithography process and an etching process similar to the processes discussed above with respect to forming the patterned stack 103 As a result, openings 118 and 120 are formed in the isolation structure 116, as shown in FIGS. IF-1 and 1F-2 in accordance with some embodiments.

Next, the cap layer 114 over sidewalls of the openings 118 and 120 are removed, as shown in FIGS. 1G-1 and 1G-2 in accordance with some embodiments. In some embodiments, the cap layer 114 may be etched from the openings 118 and 120 to expose the channel layer 112 on the sidewalls of the openings 118 and 120. The cap layer 114 may be etched by an etching process such as a dry etching process or a wet etching process. In some embodiments, the cap layer 114 is etched by a dry etching process. The dry etching process may include using a fluorine-based etchant gas, such as SF₆, CₓF_{y} (where x and y are positive integers), NF₃, or combinations thereof.

FIG. 1G-3 shows cross-sectional representations taken along line 3-3 in FIG. 1G-2. As shown in FIG. 1G-3, after etching the cap layer 114, a portion of the channel layer 112 remains over the bottom surface of the opening 118 (and the opening 120), such that the channel layer 112 has an L-shape over the sidewall and the bottom surface of the opening 118 (and the opening 120) in the cross-sectional view.

Afterwards, a mask structure 121 is formed over the isolation structure 116 and the ferroelectric layer 110 covering the stack 103, as shown in FIGS. 1H-1 and 1H-2 in accordance with some embodiments. A mask structure 121 may include a bottom layer 122, a middle layer 124, and a top layer 126. The bottom layer 122, the middle layer 124, and the top layer 126 may each include a photoresist or photo-sensitive material, one or more other suitable materials, or combinations thereof. The bottom layer 122 may include CₓH_{y}O_{z}, the middle layer 124 may include SiCₓH_{y}O_{z}, and the top layer 126 may include a photosensitive material (e.g., a photoresist), where x, y, and z are positive integers. The bottom layer 122, the middle layer 124, and the top layer 126 are deposited using a spin-on process, other applicable processes, or combinations thereof.

As shown in FIGS. 1H-1 and 1H-2, the top layer 126 of the mask structure 121 is patterned. As a result, an opening 128 is formed in the top layer 126. The middle layer 124 is exposed by the opening 128. The top layer 126 is patterned by a photolithography process discussed in detail above.

Afterwards, the middle layer 124 is patterned using the patterned top layer 126 as an etch mask. As a result, the opening 128 is transferred to the middle layer 124 (not shown). The patterned top layer 126 may be removed during and/or after patterning the middle layer 124. Similarly, the bottom layer 122 is then patterned and etched using the patterned middle layer 124 as an etch mask. As a result, the opening 128 is transferred into the bottom layer 122 (not shown). The patterned middle layer 124 may be removed during and/or after the patterning of the bottom layer 122.

Next, the middle layer 124 and the bottom layer 122 are sequentially patterned using one or more etching processes, other applicable processes, or combinations thereof. The etching process may be a dry etching process, other applicable processes, or combinations thereof. As shown in FIGS. 1I-1 and 1I-2, the patterned middle layer 124 and bottom layer 122 are used as an etch mask to pattern the isolation structure 116, thereby removing a portion of the isolation structure 116 between opposing potions of the cap layer 114 near the opening 118. As a result, the opening 118 is enlarged in the isolation structure 116 while the cap layer 114 remains over a portion of the sidewall of the opening 118. In other words, the opening 118 is enlarged between the cap layers 114 toward the adjacent opening 120. After patterning the isolation structure 116, the patterned middle layer 124 and bottom layer 122 are removed by resist stripping and/or plasma ashing.

In some embodiments, the isolation structure 116 has a tapered sidewall in the openings 118 and 120. In some embodiments, the isolation structure 116 has a rounded corner near the top of the openings 118 and 120.

Afterwards, a source structure 130 and a drain structure 132 are formed in the openings 118 and 120, respectively, over the isolation structure 116 as shown in FIGS. 1J-1, 1J-2, and 1J-3 in accordance with some embodiments. The source structure 130 and the drain structure 132 may each include a metal (e.g., Co, Ni, W, Ti, Ta, Cu, Al, Ru, Mo, TiN, TaN, other suitable metals, or combinations thereof), metal alloys, poly-Si, other applicable conductive materials, or combinations thereof. The source structure 130 and the drain structure 132 may be formed by a CVD process, a PVD process, (e.g., evaporation or sputter), an ALD process, an electroplating process, another suitable process, or combinations thereof to deposit the conductive materials of the source structure 130 and the drain structure 132 in the openings 118 and 120, respectively, and then a planarization process such as a CMP process or an etch back process may be performed to remove excess conductive materials formed over the top surface of the ferroelectric layer 110.

In some embodiments, the source structure 130 is a source line structure 130, and the drain structure 132 is a bit line structure of a ferroelectric random access memory (FeRAM) cell. In some embodiments, the gate layer 106 is a word line layer 106 of the FeRAM cell.

FIG. 1J-3 is a cross-sectional representation taken along line 3-3 in FIG. 1J-2. As shown in FIG. 1J-3, since a portion of the channel layer 112 remains over the bottom surface of the opening 118, the source structure 130 is configured as a T-shape in the cross-sectional view. In some embodiments, a portion of the channel layer 112 is under the source structure 130. Similarly, though not depicted, the drain structure 132 is also configured as a T-shape in a cross-sectional view along a line parallel to the line 3-3.

Next, a mask structure 151, including a bottom layer 152, a middle layer 154, and a top layer 156, is formed over the patterned isolation structure 116 and the ferroelectric layer 110 covering the stack 103, as shown in FIGS. 1K-1 and 1K-2 in accordance with some embodiments. The multi-layer mask structure 141 may be substantially the same as the mask structure 121 in composition. For example, the bottom layer 152, the middle layer 154, and the top layer 156 have substantially the same composition as the bottom layer 122, the middle layer 124, and the top layer 126, respectively, as discussed above. The multi-layer mask structure 141 is patterned to form openings 134 in the top layer 156, which expose the middle layer 154. The processes for forming and patterning the mask structure 151 may be the same as, or similar to, those used to form the mask structure 121 in the embodiments as shown in FIGS. 1H-1 and 1H-2. For purposes of brevity, the descriptions of these processes are not repeated herein.

Next, as shown in FIGS. 1L-1 and 1L-2, the patterned mask structure 151 is used as an etch mask to further pattern the underlying isolation structure 116 by an etching process. As a result, the isolation structure 116, the cap layer 114, and the channel layer 112 on opposite sides of the source structure 130 and the drain structure 132 are removed, resulting in the openings 136. In some embodiments, the isolation structure 116, the cap layer 114, and the channel layer 112 on opposite sides of the source structure 130 and the drain structure 132 are removed completely to prevent electrical short-circuits. The etching process may be a dry etching process or a wet etching process.

Next, as shown in FIGS. 1M-1, 1M-2, and 1M-3, isolation structures 138 are formed in the openings 136. The processes and the materials for forming the isolation structure 116 may be the same as, or similar to, those used to form the isolation structure 116 in the embodiments shown in FIGS. 1E-1 and 1E-2. For purposes of brevity, the descriptions of these processes are not repeated herein. In some embodiments, the isolation structure 138 is configured to provide isolation between adjacent FeRAM cells. In the present embodiments, each FeRAM cell is interposed between two portions of the isolation structure 138.

As shown in FIGS. 1M-1, 1M-2, and 1M-3, the source structure 130 has an extended portion between the cap layers 114, while the interface between the drain structure 132 and the isolation structure 116 is aligned with the interface between the drain structure 132 and the cap layer 114. In some embodiments, the source structure 130 has a first portion between the channel layers 112 and a second portion that extends between the cap layers 114. In some embodiments, the contact area between the source structure 130 and the cap layer 114 is greater than the contact area between the drain structure 132 and the cap layer 114. In some embodiments, a length of the source structure 130 along the channel layer 112 is greater than a length of the drain structure 132 along the channel layer 112. In some embodiments, the sidewall of the cap layer 114 is aligned with the sidewall of the isolation structure 116. Because only the source structure 130 is extended and the drain structure 132 is not, energy band offset and electric field induced by an applied voltage on the drain structure 132 may be minimized, leading to improvement in memory window of the FeRAM cell.

In some embodiments as shown in FIG. 1M-2, an extended distance E1 of the source structure 130 towards the drain structure 132 is about 5 nm to about 125 nm. If the extended distance E1 is too long, the area of the FeRAM cell may be too great. If the extended distance E1 is too short, improvement in the memory window may not be enough to bring about enhancement in device performance. In some embodiments as shown in FIG. 1M-2, the drain structure 132 does not extend toward the source structure 130.

In some embodiments as shown in FIG. 1M-2, the isolation structure 116 has a thickness T1 of about 30 nm to about 200 nm. If the isolation structure 116 is too thick, the area of the FeRAM cell may be too great. If the isolation structure 116 is too thin, the isolation between the source structure 130 and the drain structure 132 may be not enough to prevent electrical short-circuits.

It should be noted that there should be no seam or void in the isolation structure 116. A seam or a void in the isolation structure 116 may cause electrical short-circuits between the source structure 130 and the drain structure 132.

In some embodiments as shown in FIG. 1M-2, the isolation structures 138 adjacent to the source structure 130 and the drain structure 132 has a thickness T2 and T3, respectively. In some embodiments, the thicknesses T2 and T3 are each about 30 nm to about 300 nm. If the thicknesses T2 and T3 of the isolation structures 138 are too large, the area of the FeRAM cell may be too great. If the thickness T2 and T3 of the isolation structures 138 is too small, the isolation between adjacent FeRAM cells may be not enough.

In some embodiments as shown in FIG. 1M-2, the channel layer 112 has a thickness C1 of about 5 nm to about 50 nm. The thickness C1 of the channel layer 112 may depend on the electrical demands for the FeRAM cell.

In some embodiments as shown in FIG. 1M-2, the cap layer 114 has a thickness C2 of about 5 nm to about 50 nm. If the cap layer 114 is too thin, the channel layer 112 may be inadvertently damaged when forming the openings 118 and 112 for the source structure 130 and the drain structure 132.

In some embodiments as shown in FIG. 1M-2, a ratio of a length L1 of the cap layer 114 to a length L2 of the channel layer 112 is about 0.1 to about 0.6. If the ratio of the length L1 to the length L2 is too small, the channel length may be too short, and the short-channel effect may be worsened. If the ratio of the length L1 to the length L2 is too large, the source structure 130 and the drain structure 132 may be too small, and the resistance may be higher than desired. The on-current may also be reduced as a result.

FIG. 1M-3 is a cross-sectional representation taken along line 3-3 in FIG. 1M-1. As shown in FIG. 1M-3, the semiconductor memory structure 10a includes an FeRAM cell with two ferroelectric field-effect transistors (FeFETs) sharing a common source structure 130 and a common drain structure 132.

With only the source structure 130 extended relative to the drain structure 132, the voltage applied on the drain structure 132 has less impact on the energy band offset and the electric field that affects the polarization in the ferroelectric layer 110. Therefore, the memory window of the FeRAM cells may be improved.

Many variations and/or modifications may be made to the embodiments of the disclosure. Some processes or components are the same as, or similar to, those described in the embodiments above, and therefore the descriptions of these processes and components are not repeated herein. FIG. 2 is a top view of an example modified semiconductor memory structure 10b, in accordance with some embodiments of the disclosure. The difference from the embodiments described above is that, as shown in FIG. 2 in accordance with some embodiments, the ratio of the length L1 of the cap layer 114 to the length L2 of the channel layer 112 is greater than the ratio of the length L1 to the length of L2 in the embodiments shown in FIG. 1M-2.

In some embodiments as shown in FIG. 2, the ratio of the length L1 of the cap layer 114 to the length L2 of the channel layer 112 is about 0.04 to about 0.81. With a relatively longer cap layer 114 and a greater ratio of the length L1 of the cap layer 114 to the length L2 of the channel layer 112, the device area may be reduced. Therefore, the density of the FeRAM cells may be increased, and the on-current of the FeRAM cells may be higher.

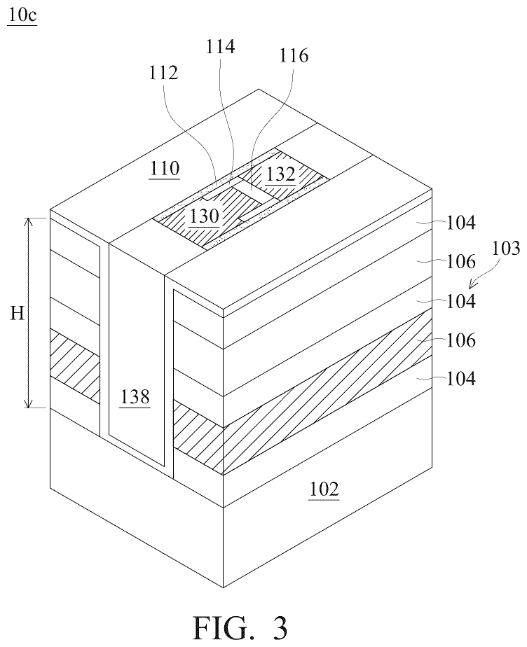

FIG. 3 is a perspective view of another example modified semiconductor memory structure 10c, in accordance with some embodiments of the disclosure. The difference from the embodiments described above is that, as shown in FIG. 3 in accordance with some embodiments, the stack 103 includes multiple, alternating gate layers 106 and isolation layers 104.

As shown in FIG. 3, more than one gate layers 106 and isolation layers 104 are alternatively stacked to form the stack 103 over the substrate 102. Afterwards, as shown in FIG. 3 and similar to the embodiments discussed above with respect to FIGS. 1A-1 to IM-3, the ferroelectric layers 110, the channel layer 112, and the cap layer 114 are formed beside the stack 103. The source structure 130 and the drain structure 132 are formed between the channel layers 112 and separated by the isolation structure 116. The isolation structures 138 are formed over opposite sides of the source structure 130 and the drain structure 132.

In addition to the benefit offered by the extended source structure 130 relative to the drain structure 132 discussed above, the multiple gate layers 106 and isolation layers 104 result in more FeFETs in the same area, and the memory storage capacity may be increased accordingly. In some embodiments as shown in FIG. 3, the height H of the stack 103 is about 60 nm to about 3000 nm. If the stack 103 is too high, etching the stack 103 to expose the substrate 102 may be difficult.

It should be noted that, although in the embodiments of FIG. 3, there are two gate layers 106 and three isolation layers 104 in the stack 103. The numbers of layers of the gate layers 106 and the isolation layers 104 are not limited thereto, depending on the design and etching process limitation. In some embodiments, the stack 103 includes at least two gate layers 106.

FIG. 4 is a top view of yet another modified semiconductor memory structure 10d, in accordance with some embodiments of the disclosure. The difference from the embodiments described above is that, as shown in FIG. 4 in accordance with some embodiments, the drain structure 132 also has an extending portion towards the source structure 130.

As shown in FIG. 4, the source structure 130 and the drain structure 132 extend towards each other between the cap layers 114. In addition, the source structure 130 and the drain structure 132 are separated by the isolation structure 116. In some embodiments, the source structure 130 extends more than the drain structure 132. In this regard, a length LS1 of the extending portion of the source structure 130 is greater than a length LD1 of the extending portion of the drain structure 132. In some embodiments, the area of the source structure 130 is greater than the area of the drain structure 132 in the top view. With the extending portion of the source structure 130 being longer than the extending portion of the drain structure 132, the memory window may be improved.

With source structure 130 has an extending portion longer than the extending portion of the drain structure 132, the voltage applied on the drain structure 132 has less impact on the energy band and the electric field affecting polarization in the ferroelectric layer 110. Therefore, the memory window of the FeRAM cells may be improved.

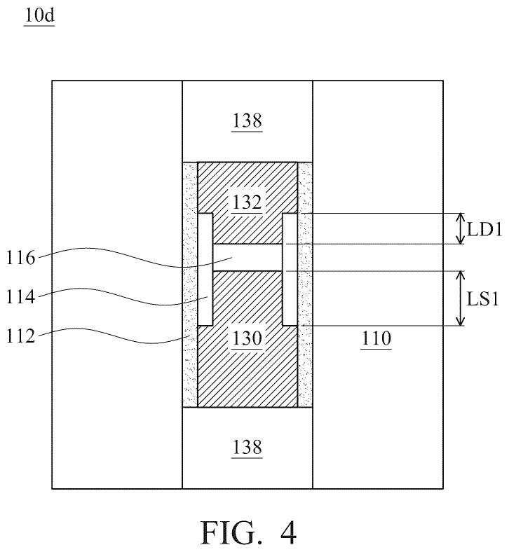

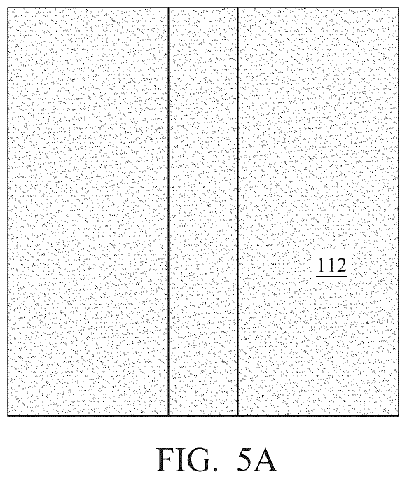

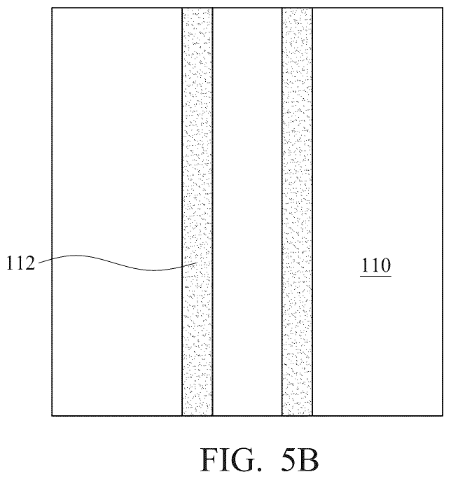

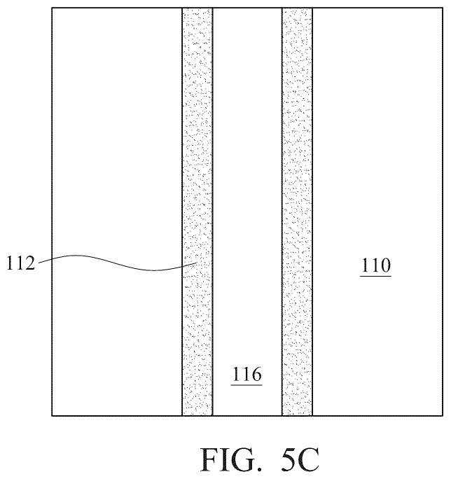

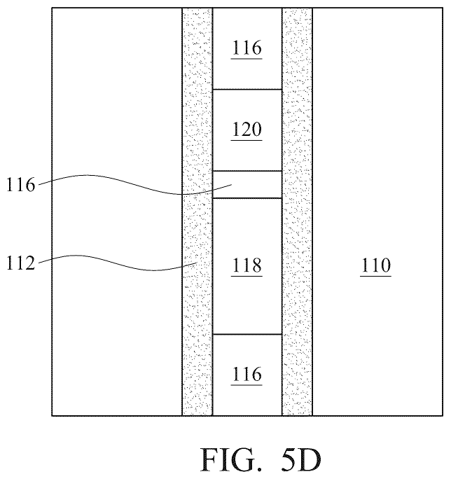

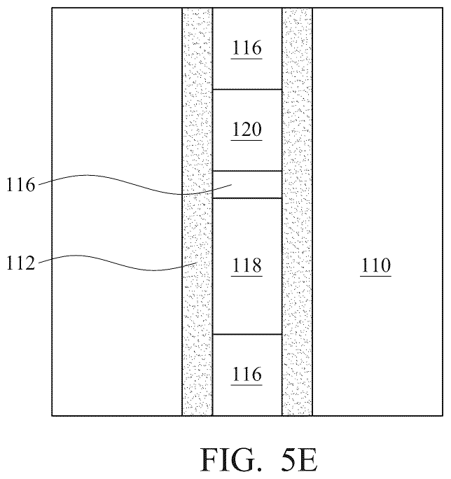

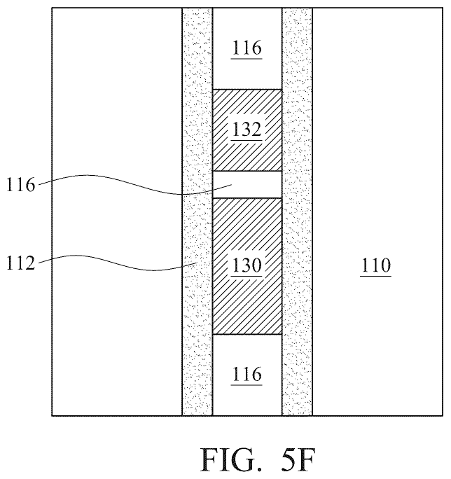

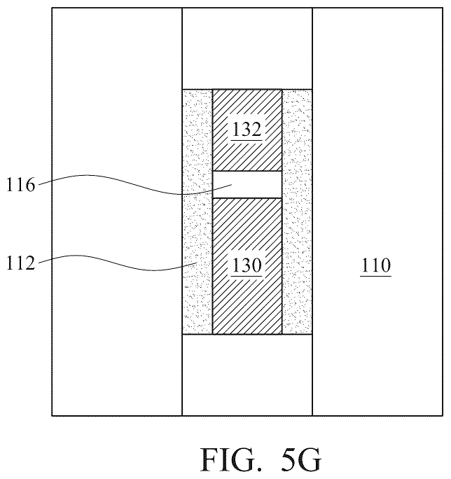

FIGS. 5A-5H are top views of various stages of forming another modified semiconductor memory structure 10e, in accordance with some embodiments of the disclosure. The difference from the embodiments described above is that, as shown in FIGS. 5A and 5B, in accordance with some embodiments, the cap layer 114 is not formed, and the channel layer 112 over the stack 103 and the bottom surface of the opening 108 is etched after depositing the channel layer 112. Embodiments depicted in FIGS. 5A and 5B are in contrast to the embodiments depicted in FIGS. 1C-2 and 1D-2, respectively. Because of the absence of the cap layer 114, etching the channel layer 112 removes the portions of the channel layer 112 from the bottom surface of the opening 108.

Next, as shown in FIG. 5C, the isolation structure 116 is formed between the channel layers 112. As shown in FIG. 5D, the isolation structure 116 is patterned and openings 118 and 120 are formed in the isolation structure 116 between the channel layers 112. Next, as shown in FIG. 5E, the isolation structure 116 is patterned and the opening 118 is enlarged between the channel layers 112. Afterwards, as shown in FIG. 5F, the source structure 130 and the drain structure 132 are formed in the openings 118 and 120, respectively. Later, as shown in FIG. 5G, the channel layer 112 and the isolation structure 116 are patterned, and the channel layer 112 and the isolation structure 116 on the opposite sides of the source structure 130 and the drain structure 132 are removed. Afterwards, as shown in FIG. 5H, isolation structures 138 are formed on opposite sides of the source structure 130 and the drain structure 132.

The processes and the materials for forming the isolation structure 116, the openings 118 and 120, the source structure 130, the drain structure 132, and the isolation structures 138 may be the same as, or similar to, those discussed above with respect to the embodiments shown in FIGS. 1E-2, 1F-2, 1H-2, 1I-2, 1J-2, 1K-2, 1L-2, and 1M-2. For purposes of brevity, the descriptions of these processes are not repeated herein.

Compared to the previous embodiments as shown in FIG. 1M-2, the cap layer 114 is not formed between the channel layer 112 and the source structure 130/drain structure 132. Therefore, in addition to providing the benefits of improved memory window, some patterning processes may be omitted, and the cost and time required for production may be reduced.

As shown in FIG. 5H, both of the source structure 130 and the drain structure 132 each have a rectangular shape in the top view. In some embodiments, a length LS2 of the source structure 130 is longer than a length LD2 of the drain structure 132 along the channel layer 112. Therefore, the memory window may be improved for reasons discussed above.

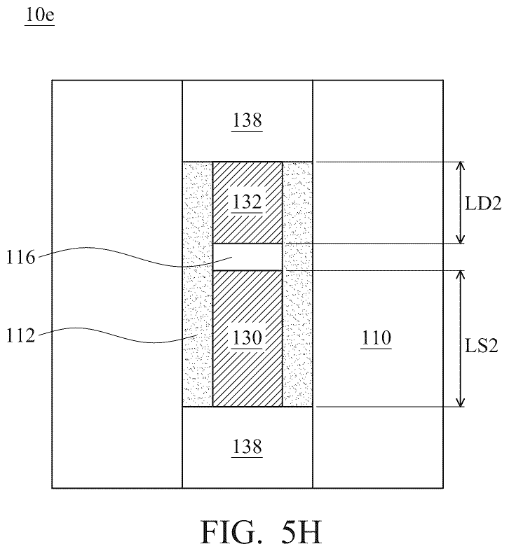

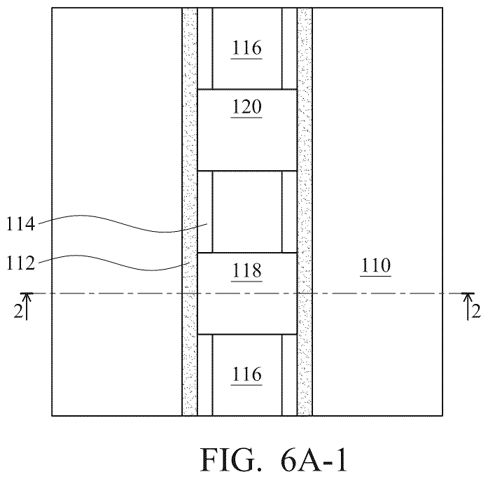

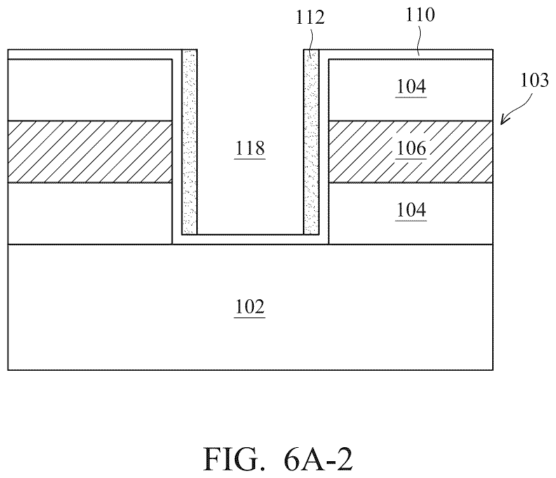

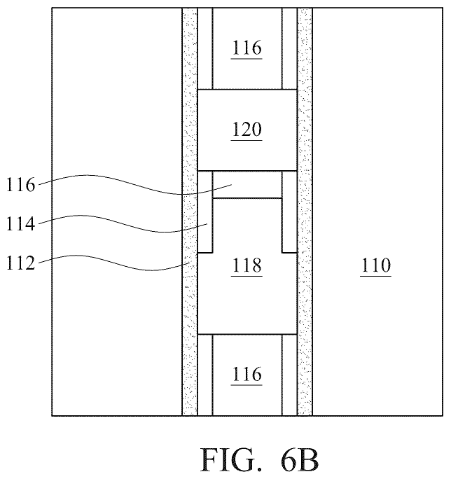

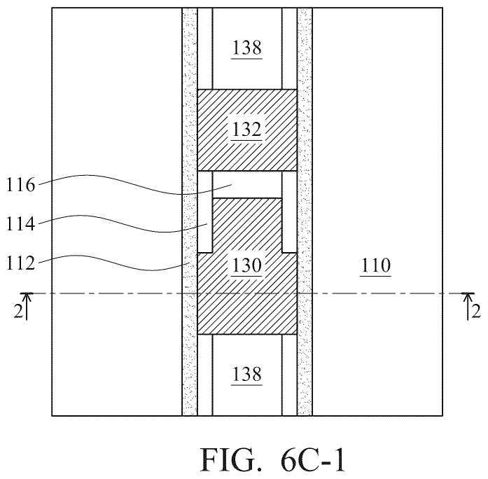

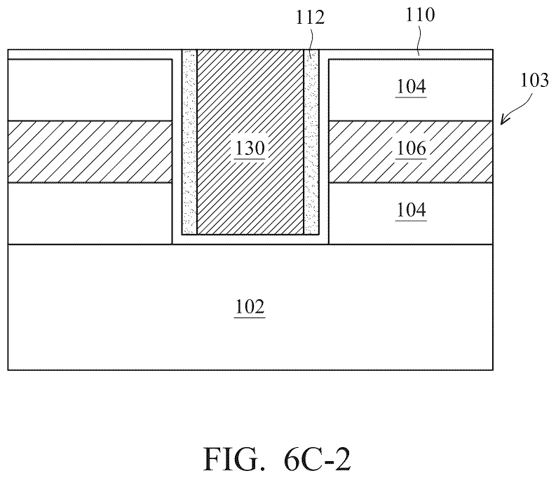

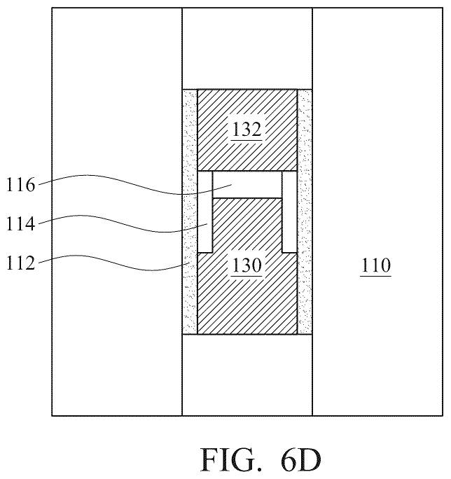

FIGS. 6A-1, 6B, 6C-1, 6D-6E are top views of various stages of forming still another modified semiconductor memory structure 10f, in accordance with some embodiments of the disclosure. FIG. 6A-2 shows a cross-sectional representation taken along line 2-2 in FIG. 6A-1. The difference from the embodiments described above is that, as shown in FIGS. 6A-1 and 6A-2, after etching the cap layer 114, the portion of the channel layer 112 over the bottom surface of the openings 118 and 120 is removed.

Afterwards, as shown in FIG. 6B, the isolation structure 116 is patterned and the opening 118 is enlarged between the cap layers 114. Afterwards, as shown in FIG. 6C-1, the source structure 130 and the drain structure 132 are formed in the openings 118 and 120, respectively. FIG. 6C-2 shows a cross-sectional representation taken along line 2-2 in FIG. 6A-1. As shown in FIG. 6C-2, since the channel layer 112 over the bottom surface of the opening 118 is removed, the source structure 130 has a rectangular shape in the cross-sectional view rather than a T-shape as depicted in FIG. 1J-3.

Later, as shown in FIG. 6D, the channel layer 112, the cap layer 114, and the isolation structure 116 are patterned, and the channel layer 112, the cap layer 114, and the isolation structure 116 on opposite sides of the source structure 130 and the drain structure 132 are removed. Afterwards, as shown in FIG. 6E, isolation structures 138 are formed on opposite sides of the source structure 130 and the drain structure 132.

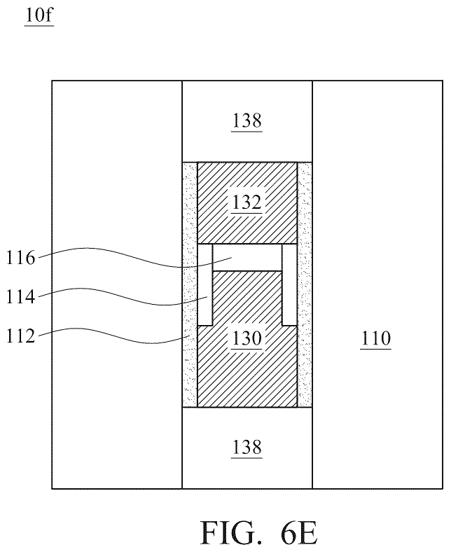

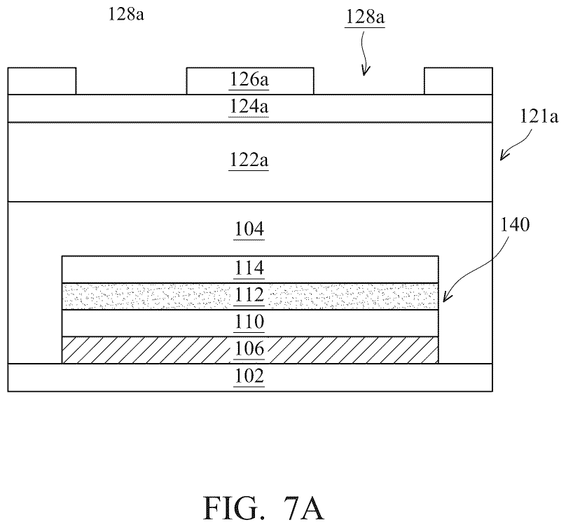

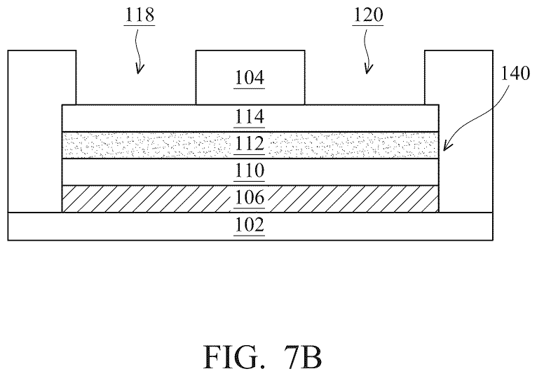

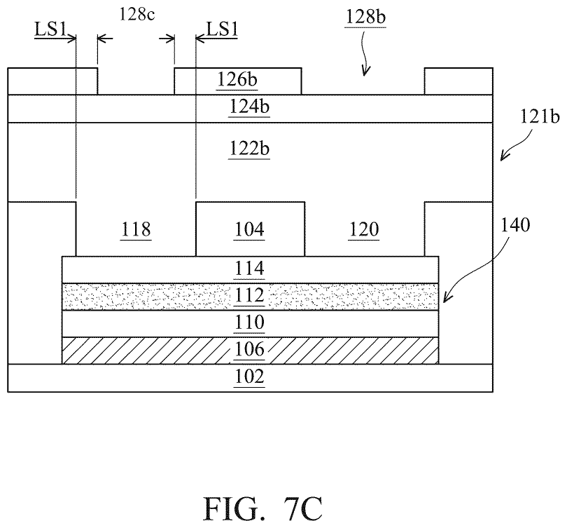

FIGS. 7A-7F are cross-sectional views of various stages of forming another planar semiconductor memory structure 10g, in accordance with some embodiments of the disclosure. The difference from the embodiments described above is that, as shown in FIG. 7A, in accordance with some embodiments, the semiconductor memory structure is a planar device rather than a three-dimensional device as depicted in semiconductor memory structures 10a-10g.

In some embodiments as shown in FIG. 7A, a stack 140 including the gate layer 106, the ferroelectric layer 110, the channel layer 112, and the cap layer 114 is formed over the substrate 102. As shown in FIG. 7A, the gate layer 106 is formed over the substrate 102, and the ferroelectric layer 110 is formed over the gate layer 106. In addition, the channel layer 112 is formed over the ferroelectric layer 110, and the cap layer 114 is formed over the channel layer 112. As shown in FIG. 7A, the isolation layer 104 is formed over the cap layer 114, and the isolation layer 104 also covers the sidewalls of the stack 140. In some embodiments, the isolation layer 104 surrounds the stack 140.

The processes and the materials for forming the substrate 102, the gate layer 106, the ferroelectric layer 110, the channel layer 112, the cap layer 114, and the isolation layer 104 may be the same as, or similar to, those discussed above with respect to the embodiments shown in FIGS. 1C-1 and 1E-1. For purposes of brevity, the descriptions of these processes are not repeated herein.

Next, as shown in FIG. 7A, a patterned mask structure 121a including a bottom layer 122a, a middle layer 124a, and a top layer 126a is formed over the isolation layers 104. As shown in FIG. 7A, the mask structure 121a is patterned to form openings 128a in the top layer 126a, which exposes the middle layer 124a. Next, as shown in FIG. 7B, the isolation layer 104 is patterned by the patterned mask structure 121a to form the openings 118 and 120 in the isolation layer 104.

The processes and the materials for forming the patterned mask structure 121a may be the same as, or similar to, those used to form the patterned mask structure 121 in the embodiments as shown in FIG. 1H-1. For purposes of brevity, the descriptions of these processes are not repeated herein.

Afterwards, as shown in FIG. 7C, a patterned mask structure 121b including a bottom layer 122b, a middle layer 124b, and a top layer 126b is formed over the patterned isolation layer 104, such that the bottom layer 122b fills the openings 118 and 120. As shown in FIG. 7C, openings 128b and 128c are formed in the top layer 126b. As shown in FIG. 7C, the opening 128c over the opening 118 is narrower than the opening 118, and the opening 128b over the opening 120 has the same width with the opening 120.

Accordingly, as shown in FIG. 7C, the top layer 126b extends from both sides to partially cover the opening 118. In some embodiments, an extended distance LS1 of the top layer 126b over the opening 118 is about 5 nm to about 125 nm from each side. If the extended distance LS1 is too long, the area of the FeRAM cell may be too large. If the extended distance LS1 is too short, improvement in the memory window may be not enough. In some embodiments, the sidewall of the opening 128b in the top layer 126b is substantially aligned with the sidewall of the opening 120 in the isolation layer 104.

Next, as shown in FIG. 7D, the bottom layer 122b is patterned by the patterned top layer 126b. The middle layer 124b and the top layer 126b are subsequently removed by a suitable method. In some embodiments, portions of the patterned bottom layer 122b remain over the sidewalls of the opening 118. In some embodiments, the bottom layer 122b in the opening 118 is in contact with the cap layer 114. In some embodiments, the sidewalls of the bottom layer 122b are aligned with the sidewalls of the isolation layer 104 in the opening 120.

Next, as shown in FIG. 7E, the cap layer 114 is patterned by the patterned bottom layer 122b, and the patterned bottom layer 122b is removed thereafter. Therefore, portions of the resulting cap layer 114 extend beyond the sidewalls of the isolation layer 104 and over the bottom surface of the opening 118.

The processes and the materials for forming the patterned mask structure 121b and patterning the cap layer 114 may be the same as, or similar to, those used to form the patterned mask structure 121 and to etch the cap layer 114 in the embodiments as shown in FIGS. 1H-1 and 1I-1. For purposes of brevity, the descriptions of these processes are not repeated herein.

Next, the source structure 130 and the drain structure 132 are formed in the openings 118 and 120, respectively, as shown in FIG. 7F in accordance with some embodiments, resulting in a planar FeFET. A planarization process, such as a CMP process, is performed to remove excess conductive materials deposited over the isolation layer 104 to form the source structure 130 and the drain structure 132. Therefore, the top surface of the source structure 130 and the drain structure 132 is substantially level with the top surface of the isolation layer 104.

As shown in FIG. 7F, the source structure 130 extends towards the drain structure 132 while the drain structure does not extend towards the source structure 130. Therefore, for reasons discussed above, the memory window of the planar semiconductor memory structure 10g may be improved. In some embodiments, since the source structure 130 extends on both sides, it is configured to have a T-shape in a cross-sectional view.

The processes and the materials for forming the source structure 130 and the drain structure 132 may be the same as, or similar to, those used to form the source structure 130 and the drain structure 132 in the embodiments as shown in FIG. 1J-1. For purposes of brevity, the descriptions of these processes are not repeated herein.

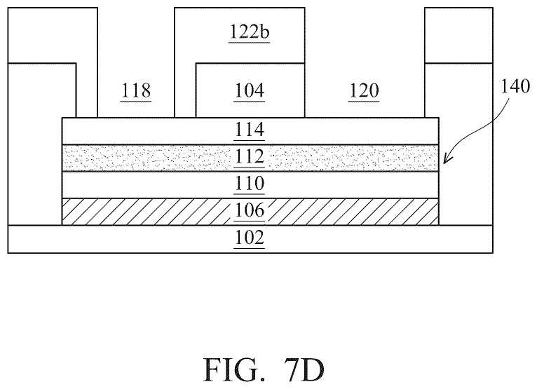

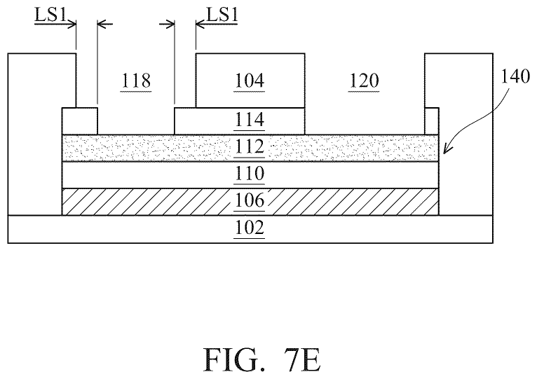

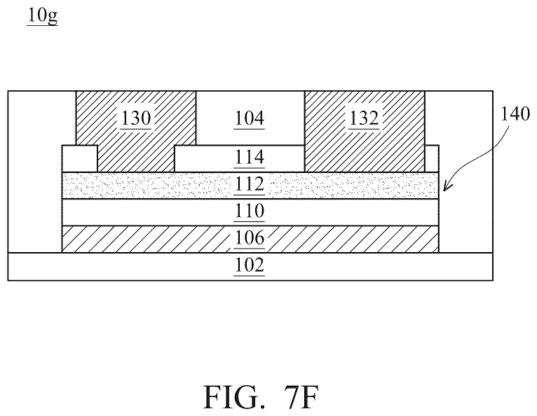

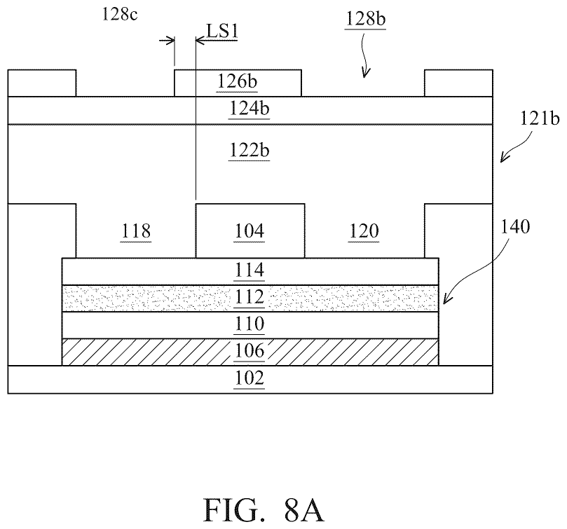

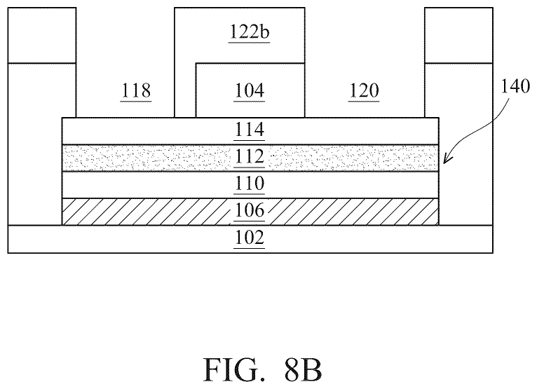

FIGS. 8A-8D are cross-sectional views of various stages of forming a modified planar semiconductor memory structure 10h, in accordance with some embodiments of the disclosure. The difference from the embodiments described in FIGS. 7A to 7F is that, as shown in FIG. 8A, in accordance with some embodiments, the top layer 126b of the patterned mask structure 121b extends only at one side of the opening 128c over the opening 118.

As shown in FIG. 8A, the patterned mask structure 121b including the bottom layer 122b, the middle layer 124b, and the top layer 126b is formed over the patterned isolation layer 104. As shown in FIG. 8A, the openings 128b and 128c are formed in the top layer 126. As shown in FIG. 8A, the top layer 126b extends from one side of the opening 128 covering the opening 118. In some embodiments, the top layer 126b extends from the opening 120 to partially cover the opening 118. In addition, the opening 128b over the opening 120 has the same width with the opening 120.

As shown in FIG. 8A, the top layer 126b has an extending portion covering the opening 118 at only one side. In some embodiments, the extended distance LS1 of the top layer 126 over the opening 118 is about 5 nm to about 125 nm from the side near the opening 120. If the extended distance LS1 is too long, the area of the FeRAM cell may be too large. If the extended distance LS1 is too short, improvement in the memory window may be not enough. In some embodiments, one of the sidewalls of the opening 128c away from the opening 120 (the non-extended side) is aligned with the sidewall of the opening 118. In some embodiments, the sidewalls of the opening 128b in the top layer 126 are substantially aligned with the sidewalls of the opening 120 in the isolation layer 104.

Next, as shown in FIG. 8B, the bottom layer 122b is patterned by the patterned top layer 126b. In some embodiments, a portion of the patterned bottom layer 122b remains over one of the sidewalls of the opening 118 near the opening 120. In some embodiments, one of the sidewalls of the bottom layer 122b is aligned with the sidewall of the isolation layer 104 away from the opening 120. In some embodiments, the sidewalls of the bottom layer 122b are aligned with the sidewalls of the isolation layer 104 in the opening 120.

Next, as shown in FIG. 8C, the cap layer 114 is patterned by the patterned bottom layer 122b, and the patterned bottom layer 122b is removed thereafter. Therefore, the cap layer 114 extends beyond one of the sidewalls of the patterned isolation layer 104 and over the bottom surface of the opening 118 at the side near the opening 120.

The processes and the materials for forming the patterned mask structure 121b and patterning the cap layer 114 may be the same as, or similar to, those used to form the patterned mask structure 121b and to etch the cap layer 114 in the embodiments as shown in FIGS. 7C-7E. For purposes of brevity, the descriptions of these processes are not repeated herein.

Next, the source structure 130 and the drain structure 132 are formed in the openings 118 and 120, respectively, as shown in FIG. 8D in accordance with some embodiments. As shown in FIG. 8D, the source structure 130 includes an extending portion towards the drain structure 132 while the source structure 130 does not include any extending portion. Therefore, for reasons discussed above, the memory window of the planar semiconductor memory structure 10h may be improved. In some embodiments, since the source structure 130 includes a one-sided extension, it is configured to have an inverted L-shape in a cross-sectional view. In the present embodiments, referring to FIG. 8D, the source structure 130 extends toward the drain structure 132. In comparison, referring to FIG. 7F, the source structure 130 extends both toward and away from the drain structure 132.

The processes and the materials for forming the source structure 130 and the drain structure 132 may be the same as, or similar to, those used to form the source structure 130 and the drain structure 132 in the embodiments as shown in FIG. 7F. For purposes of brevity, the descriptions of these processes are not repeated herein.

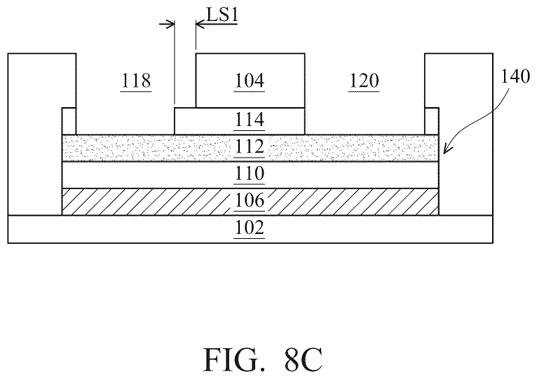

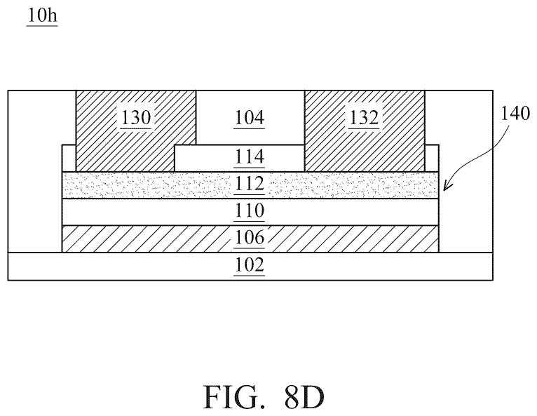

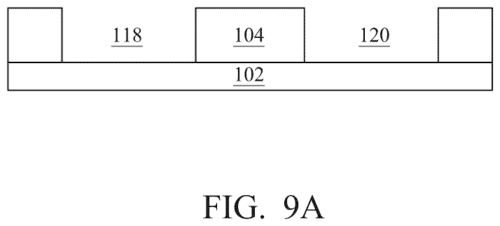

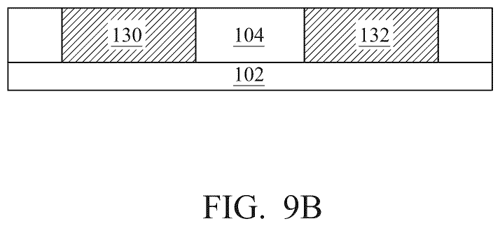

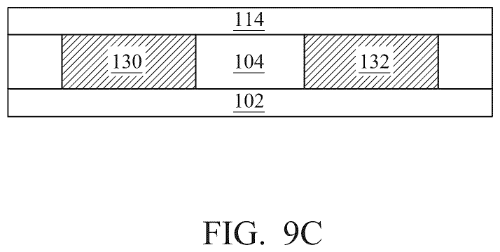

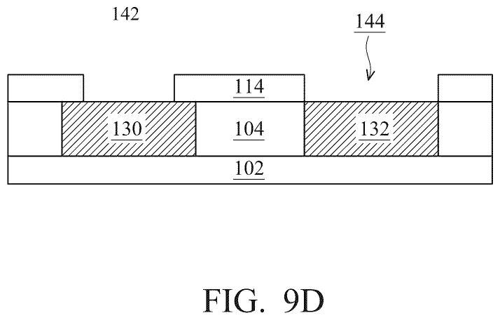

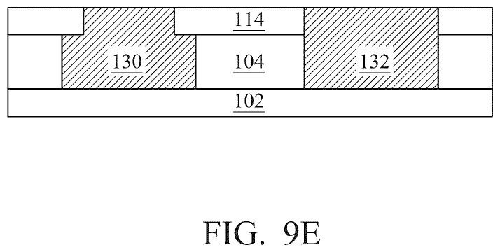

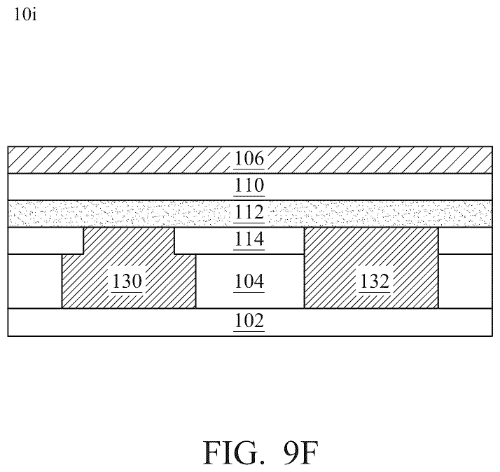

FIGS. 9A-9F are cross-sectional views of various stages of forming still another planar semiconductor memory structure 10i, in accordance with some embodiments of the disclosure. The difference from the embodiments described in FIGS. 7A-8D is that, as shown in FIGS. 9A and 9B, in accordance with some embodiments, the source structure 130 and the drain structure 132 are in direct contact with the substrate 102.

As shown in FIG. 9A, the isolation layer 104 is formed over the substrate 102. As shown in FIG. 9A, the isolation layer 104 is patterned to forming the openings 118 and 120 in the isolation layer 104.

Next, as shown in FIG. 9B, the source structure 130 and the drain structure 132 are formed in the openings 118 and 120, respectively. A planarization process, such as a CMP process, is performed to remove excess conductive materials from the isolation layer 104 to form the source structure 130 and the drain structure 132. Therefore, the top surface of the source structure 130 and the drain structure 132 is substantially level with the top surface of the isolation layer 104.

The processes and the materials for forming the isolation layer 104, the source structure 130, and the drain structure 132 may be the same as, or similar to, those used to form the isolation layer 104, the source structure 130, and the drain structure 132 in the embodiments as shown in FIGS. 7A, 7B, and 7F. For purposes of brevity, the descriptions of these processes are not repeated herein.

Afterwards, the cap layer 114 is deposited over the isolation layer 104, the source structure 130, and the drain structure 132, as shown in FIG. 9C in accordance with some embodiments. The cap layer 114 is then patterned to form openings 142 and 144 in the cap layer 114 over the source structure 130 and the drain structure 132, respectively, as shown in FIG. 9D in accordance with some embodiments. As shown in FIG. 9D, the opening 142 over the source structure 130 is narrower than the source structure 130. In some embodiments, the cap layer 114 covers a portion of the source structure 130. In some embodiments, sidewalls of the opening 144 over the drain structure 132 and the drain structure 132 have the same width. In some embodiments, the sidewalls of the opening 144 over the drain structure 132 are aligned with the sidewalls of the drain structure 132.

The processes and the materials for forming and patterning the cap layer 114 may be the same as, or similar to, those used for forming and patterning the cap layer 114 in the embodiments as shown in FIGS. 7C-7E. For purposes of brevity, the descriptions of these processes are not repeated herein.

Next, as shown in FIG. 9E, a conductive material is formed in the openings 142 and 144 over the source structure 130 and the drain structure 132, respectively, thereby vertically extending the source structure 130 and the drain structure 132 through the cap layer 114. As shown in FIG. 9E, the source structure 130 has an inverted T-shape and the drain structure 132 has a rectangular shape in the cross-sectional view. As shown in FIG. 9E, the source structure 130 has an extending portion towards the drain structure 132 in the isolation layer 104.

Next, as shown in FIG. 9F, a channel layer 112 is formed over the cap layer 114, and a ferroelectric layer 110 is formed over the channel layer 112. In addition, a gate layer 106 is formed over the ferroelectric layer 110. The processes and the materials for forming the channel layer 112, the ferroelectric layer 110, and the gate layer 106 may be the same as, or similar to, those used to form the channel layer 112, the ferroelectric layer 110, and the gate layer 106 in the embodiments as shown in FIG. 7A. For purposes of brevity, the descriptions of these processes are not repeated herein.

In some embodiments as shown in FIG. 9F, the source structure 130 and the drain structure 132 are formed directly over the substrate, and the gate layer 106 is formed over the source structure 130 and the drain structure 132. The gate layer 106 may be formed on the front side of the FeFET rather than the back side, as is the case in the planar semiconductor memory structure 10g and is depicted in FIGS. 7F and 8D, respectively.

As described previously, a source structure 130 with an extending portion towards the drain structure 132 is formed in a semiconductor memory structure. In some embodiments, the source structure 130 extends more than the drain structure 132. In some embodiments, the source structure 130 extends toward the drain structure 132 but the drain structure 132 does not extend toward the source structure 130. In some embodiments as shown in FIG. 2, as the ratio of the length L1 of the cap layer 114 and the length of the channel layer 112 increases, the density the resulting FeRAM cells may be higher, and the on-current may also be higher. In some embodiments as shown in FIG. 3, multiple gate layers 106 are formed in the stack 103, which may increase the storage capacity of the FeRAM cells. In some embodiments as shown in FIG. 4, the drain structure 132 also extends towards the source structure 130, but to a lesser extent than the source structure 130. In some embodiments as shown in FIG. 5H, the cap layer 114 is not formed between the source structure 130/drain structure 132 and the channel layer 112. In some embodiments as shown in FIG. 6C-2, the channel layer 112 formed over the bottom surface of the opening 118 is removed, and the source structure 130/drain structure 132 has a rectangular shape in a cross-sectional view. In some embodiments as shown in FIG. 7F, the FeFET is a planar device with the source structure 130 extending on both sides and more than the drain structure 132. In some embodiments as shown in FIG. 8D, the source structure 130 only extends in the direction toward the drain structure 132 and the source structure 130 has an inverted L-shape in a cross-sectional view. In some embodiments as shown in FIG. 9F, the source structure 130 and the drain structure 132 are in direct contact with the substrate 102, and the gate layer 106 is formed in the front side of the FeFET.

Embodiments of a semiconductor memory structure and a method for forming the same are provided. With the source structure extends more than the drain structure does, the memory window of the FeRAM cell may be improved. The semiconductor memory structure may be a three-dimensional device or a planar device.

In one aspect, a semiconductor memory structure is provided. The semiconductor memory structure includes a ferroelectric layer and a channel layer formed over the ferroelectric layer. The structure also includes a source structure and a drain structure formed over the channel layer. The structure further includes a first isolation structure formed between the source structure and the drain structure. The source structure extends over the cap layer and towards the drain structure.

In another aspect, a semiconductor memory structure is provided. The semiconductor memory structure includes gate layers formed over a substrate, ferroelectric layers formed over sidewalls of the gate layers, channel layers formed over sidewalls of the ferroelectric layers. The structure also includes cap layers formed over sidewalls of the channel layers and an isolation structure formed between the cap layers. The structure further includes a source structure and a drain structure formed on opposite sides of the isolation structure, where an area of the source structure is greater than the area of the drain structure in a top view.

In yet another aspect, a method for forming a semiconductor memory structure is provided. The method for forming a semiconductor memory structure includes alternately depositing gate layers and first isolation layers to form a stack over a substrate, patterning the stack to form a first opening to expose the substrate, and depositing a ferroelectric layer over the stack and in the first opening. The method for forming a semiconductor memory structure also includes depositing a channel layer over the ferroelectric layer, depositing a cap layer over the channel layer, and forming a second isolation layer in the first opening. The method for forming a semiconductor memory structure further includes patterning the first isolation layer to form a second opening and a third opening, thereby exposing the ferroelectric layer, patterning the second isolation layer to extend the second opening towards the third opening, and filling a conductive material in the second opening and the third opening to form a source structure and a drain structure respectively, where contact area between the source structure and the cap layer is greater than a contact area between the drain structure and the cap layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor memory structure, comprising:
depositing a gate layer between first isolation layers to form a stack over a substrate;
patterning the stack to form a first opening to expose the substrate;
depositing a ferroelectric layer over the stack and in the first opening;
depositing a channel layer over the ferroelectric layer;
depositing a cap layer over the channel layer;
forming a second isolation layer in the first opening;
patterning the second isolation layer to form a second opening and a third opening, thereby exposing the ferroelectric layer;
patterning the second isolation layer to extend the second opening towards the third opening; and
filling a conductive material in the extended second opening and the third opening to form a source structure and a drain structure, respectively, wherein a contact area between the source structure and the cap layer is greater than a contact area between the drain structure and the cap layer.

2. The method for forming a semiconductor memory structure of claim 1, further comprising removing portions of the cap layer exposed in the second opening and the third opening.

3. The method for forming a semiconductor memory structure of claim 1, further comprising, after patterning the second isolation layer to extend the second opening, patterning the second isolation layer to extend the third opening towards the extended second opening, wherein a length of extension in the third opening is less than a length of extension in the second opening.

4. The method for forming a semiconductor memory structure of claim 1, further comprising removing the channel layer from a bottom surface of the second opening and the third opening.

5. The method for forming a semiconductor memory structure of claim 1, further comprising:
removing portions of the second isolation layer and the channel layer on opposite sides of the source structure and the drain structure.

6. The method for forming a semiconductor memory structure of claim 1, wherein the stack is a first stack, the method further comprising forming a second stack over the first stack, such that the first opening is formed in the first stack and the second stack.

7. The method for forming a semiconductor memory structure of claim 1, wherein the extended second opening is longer in a first direction in a top view than the third opening.

8. The method for forming a semiconductor memory structure of claim 1, wherein the patterning the second isolation layer to form the second opening and the third opening exposes the ferroelectric layer at a bottom portion of the second opening and the third opening respectively.

9. The method for forming a semiconductor memory structure of claim 1, further comprising:
after forming the second opening and the third opening and prior to patterning the second isolation layer to the extend the second opening, performing a lateral etch of the cap layer within the first opening and the second opening, wherein the lateral etch exposes a top surface of the channel layer at a bottom of the second opening and the third opening.

10. A method for forming a semiconductor memory structure, comprising:
forming a stack comprising a first isolation layer, a gate layer and a second isolation layer over a substrate;
etching a first opening extending vertically through the stack;
forming a ferroelectric layer, a channel layer, and a cap layer on sidewalls of the first opening;
depositing a second isolation layer in the first opening;
patterning the second isolation layer to form a drain opening and a source opening, wherein the source opening is longer in a top view than the drain opening, wherein the patterning the second isolation layer includes laterally etching a portion of the cap layer in the drain opening and the source opening; and
filling a conductive material in the drain opening and the source opening to form a drain structure and a source structure, respectively.

11. The method for forming a semiconductor memory structure of claim 10, wherein a contact area between the source structure and the cap layer is greater than a contact area between the drain structure and the cap layer.

12. The method for forming a semiconductor memory structure of claim 10, wherein the patterning the second isolation layer to form the drain opening and the source opening includes:
performing a first patterning process to form the drain opening and a first portion of the source opening;
laterally etching the cap layer on the sidewalls of the drain opening and the first portion of the source opening; and
performing a second patterning process to form a second portion of the source opening.

13. The method for forming a semiconductor memory structure of claim 12, wherein the laterally etching the cap layer exposes the channel layer on sidewalls of the drain opening and the first portion of the source opening.

14. The method for forming a semiconductor memory structure of claim 13, wherein the filling the conductive material in the drain opening deposits the conductive material interfacing the exposed channel layer on the sidewall of the drain opening and the first portion of the source opening and deposits the conductive material interfacing the cap layer in the second portion of the source opening.

15. The method for forming a semiconductor memory structure of claim 10, further comprising:
after forming the drain structure and the source structure, etching the second isolation layer, the cap layer, and the channel layer adjacent to an end of each of the drain structure and the source structure.

16. A method for forming a semiconductor memory structure, the method comprising:
providing a substrate;
forming a source structure and a drain structure on the substrate;
depositing a cap layer over the source structure and the drain structure;
patterning the cap layer to form a first opening and a second opening, wherein after the patterning at least a portion of the source structure remains covered by the patterned cap layer;
filling the first opening and the second opening with conductive material to extend the source structure and the drain structure respectively; and
forming a channel layer over the extended source structure and drain structure.

17. The method of claim 16, wherein the forming the source structure and the drain structure includes forming the source structure and the drain structure directly contacting the substrate.

18. The method of claim 16, wherein the patterning the cap layer forms the first opening having sidewalls aligned with the sidewalls of the drain structure.

19. The method of claim 16, wherein the source structure has a T-shape in a cross-sectional view and the drain structure has a rectangular shape in the cross-sectional view.

20. The method of claim 16, further comprising: forming a ferroelectric layer and a gate layer over the channel layer.
